(19) United States
(12) Patent Application Publication
(10) Pub. No.: US 2005/0104213 A1
(43) Pub. Date: May 19, 2005

(54) Electric connection terminal and method of manufacturing the same, semiconductor device and method of mounting the same

(75) Inventor: Akiyoshi Aoyagi, Sagamihara-shi (JP)

Correspondence Address: HOGAN & HARTSON L.L.P., 500 S. GRAND AVENUE, SUITE 1900, LOS ANGELES, CA, 90071-2611, US

(73) Assignee: SEIKO EPSON CORPORATION

(21) Appl. No.: 10/958,980

(22) Filed: Oct. 5, 2004

(30) Foreign Application Priority Data
Oct. 10, 2003 (JP) 2003-351933

(51) Int. Cl. H01L 23/48

(52) U.S. Cl. 257/738

(57) ABSTRACT

An electric connection terminal includes a brazing material, a plurality of particles dispersed in the brazing material and made of a resin, and a conductor film that coats a surface of each of the particles.

### BACKGROUND OF THE INVENTION

1. Field of the Invention

The present invention relates to an electric connection terminal and a method of manufacturing the same, a semiconductor device and a method of mounting the same.

2. Description of Related Art

In a mode where a semiconductor device is mounted on a circuit board, it is important to relieve stress (thermal stress) applied on an external terminal of the semiconductor device. The external terminal is made of a solder ball or the like and disposed at an electric connection portion (land) of the semiconductor device. So far, a planar shape of the electric connection portion has been tried to change and thereby to avoid the stress concentration on the external terminal. However, there is a limit.

An advantage of the present invention is to alleviate the stress applied to an external terminal of a semiconductor device.

### SUMMARY OF THE INVENTION

An electric connection terminal according to an embodiment of the present invention includes a plurality of particles made of a resin and a conductor film that is coated on a surface of each of the particles. According to an embodiment of the present invention, the plurality of particles allows for the relieving of the stress applied on the electric connection terminal. The particles are dispersed in plural. Accordingly, the unwetting with the brazing material is not likely to occur. Furthermore, a surface of the particle is coated with a conductor film. Accordingly, the electric characteristics of the electric connection terminal can be improved.

In the electric connection terminal, the particles are heat-cured to form. According to this, when the electric connection terminal is heated and melted, the particles are not melted (or difficult to melt). Accordingly, even after the heating and melting, a state where a plurality of particles is dispersed can be maintained. As a result, even after the heating and melting, the stress relief of the electric connection terminal can be attained.

In the electric connection terminal, the electric connection terminal has a ball shape.

A method of manufacturing an electric connection terminal according to an embodiment of the present invention includes blending a plurality of particles made of resin in a molten brazing material and cooling the brazing material and thereby making the brazing material be the ball-like electric connection terminal containing the plurality of particles. According to an embodiment of the present invention, a plurality of particles allows for the relieving of the stress applied to the electric connection terminal. The particles are dispersed in plural. Accordingly, the unwetting with the brazing material is not likely to occur.

The method of manufacturing the electric connection terminal further includes before blending, heat-curing the particles. According to this, since when the electric connection terminal is heated and melted the particles are not melted (or difficult to melt), even after the heating and melting, a state where a plurality of particles is dispersed can be maintained. As a result, even after the heating and melting, the stress relief of the electric connection terminal can be attained.

The method of manufacturing the electric connection terminal further includes before blending, coating a surface of each of the particles with a conductor film. According to this, since a surface of the particle is coated with a conductor film, the electric characteristics of the electric connection terminal can be improved.

In the method of manufacturing the electric connection terminal, the conductor film is formed according to a plating process. Also, in the method of manufacturing the electric connection terminal, in cooling the brazing material, the brazing material is dropped and formed in the shape of a ball.

A semiconductor device involving an embodiment of the present invention includes a semiconductor chip, a substrate on which the semiconductor chip is mounted, an electric connection portion formed on the substrate and an electric connection terminal that is disposed at the electric connection portion and includes a brazing material, a plurality of particles dispersed in the brazing material and made of a resin and a conductor film that is coated on a surface of each of the particles. According to an embodiment of the present invention, the plurality of particles allows for the relieving of the stress applied to the electric connection terminal. The particles are dispersed in plural. Accordingly, the unwetting with the brazing material is difficult to occur. Furthermore, since a surface of the particle is coated with the conductor film, the electric characteristics of the electric connection terminal can be improved.

In the semiconductor device, the particles are heat-cured and formed. According to this, since when the electric connection terminal is heated and melted the particles are not melted (or difficult to melt) even after the heating and melting, a state where a plurality of particles is dispersed can be maintained. As a result, even after the heating and melting, the stress relief of the electric connection terminal can be attained. In the semiconductor device, the electric connection terminal is formed in the shape of a ball. An electronic device according to the invention includes the abovementioned semiconductor device. A method of mounting a semiconductor device according to an embodiment of the present invention includes forming a ball-like electric connection terminal including a plurality of particles made of a resin disposing the electric connection terminal at a first electric connection portion of a substrate on which a semiconductor chip is mounted and aligning the substrate to a circuit board and melting the electric connection terminal to connect the first electric connection portion and a second electric connection portion of the circuit board. According to an embodiment of the present invention, a plurality of particles allows for the relieving of the stress applied to the electric connection terminal. The particles are dispersed in plural. Accordingly, the unwetting with the brazing material is not likely to occur.

### BRIEF DESCRIPTION OF SEVERAL VIEWS OF THE DRAWINGS

FIG. 1 is a diagram showing a semiconductor device according to an embodiment of the present invention.

FIG. 2 is a diagram showing an electric connection terminal according to an embodiment of the invention.

FIG. 3 is a diagram showing a method of manufacturing an electric connection terminal according to an embodiment of the invention.

FIGS. 4A through 4C are diagrams showing a method of mounting a semiconductor device according to an embodiment of the invention.

FIG. 5 is a diagram showing a semiconductor device according to a modification example of the present invention.

FIG. 6 is a diagram showing an electronic device having a semiconductor device according to an embodiment of the invention.

FIG. 7 is a diagram showing another electronic device having a semiconductor device according to an embodiment of the invention.

### DETAILED DESCRIPTION OF THE PREFERRED EMBODIMENTS

In what follows, embodiments according to the present invention will be explained with reference to the drawings.

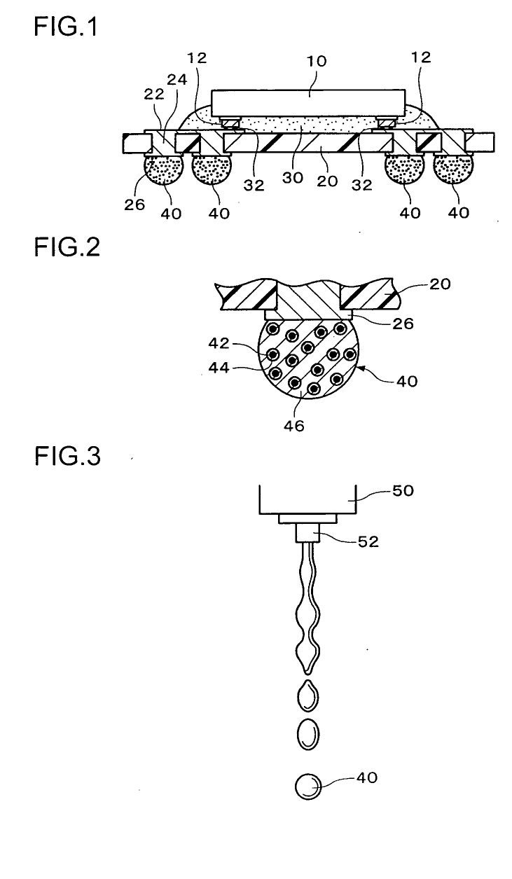

FIG. 1 is a diagram showing a semiconductor device involving an embodiment according to the present invention, and FIG. 2 is a partial enlargement diagram of FIG. 1. The semiconductor device involving the present embodiment includes a semiconductor chip 10, a substrate 20, a wiring pattern 22 (including an electric connection portion 26), and an electric connection terminal 40.

On the semiconductor chip 10, an integrated circuit (not shown in the drawing) is formed, and a plurality of electrodes 12 that is electrically connected to the integrated circuit is formed. The plurality of electrodes 12 may be formed on a surface on a side of the integrated circuit in the semiconductor chip 10. The plurality of electrodes 12 may be formed on regions along four sides or two sides of a surface of the semiconductor chip 10. The electrode 12 has a pad (such as an aluminum pad). In the case of the semiconductor chip 10 being mounted in a face-down manner on a substrate 20, the electrode 12 may further have a bump (such as gold bump) on the pad. On a surface on which the electrode 12 is formed of the semiconductor chip 10, a passivation film (not shown in the drawing) is formed.

The substrate 20, though an organic resin substrate in many cases, may be an inorganic substrate (such as a glass substrate or a ceramic substrate) or an organic/inorganic composite substrate (such as a glass/epoxy substrate). The substrate 20 may be an interposer of a semiconductor device. On the substrate 20, a wiring pattern 22 is formed. The wiring pattern 22 may be formed on both surfaces of the substrate 20. Part of the wiring pattern 22 may be made of a throughhole 24 and thereby electrical continuity between both surfaces of the substrate 20 may be established.

As shown in FIG. 1, the semiconductor chip 10 may be mounted in a face-down manner on the substrate 20. In more detail, in the semiconductor chip 10, a formation surface of the electrode 12 faces the substrate 20. The electrode 12 and the wiring pattern 22 may be electrically connected with an anisotropically conductive material 30. The anisotropically conductive material 30 may be any one of an anisotropically conductive film and an anisotropically conductive paste and is formed by dispersing a plurality of conductive particles 32 in a binder. The conductive particles 32 interpose between the electrode 12 and the wiring pattern 22 and thereby electrical connection between these can be attained. As other electrical connection modes, one due to a conductive resin paste, a metal junction (such as Au—Au junction, Au—Sn junction or solder junction) and one due to a contractive force of an insulating resin may be applied. In the case of the metal junction, a resin (underfill resin) may be filled between the semiconductor chip 10 and the substrate 20.

As a modification example, a semiconductor chip 10 may be mounted in a face-up manner on a substrate 20. In more detail, the semiconductor chip 10 may face the substrate 20 in a surface opposite to a formation surface of an electrode 12. The electrode 12 and a wiring pattern 22 may be electrically connected with a wire. In this case, an entirety of the semiconductor chip 10 is preferably sealed with a resin.

On the substrate 20, as a part of the wiring pattern 22, an electrical connection portion 26 is formed. The electric connection portion 26 may be a land. The electric connection portion 26 may be formed on a surface opposite to a surface on which the semiconductor chip 10 is mounted in the substrate 20 or on a surface the same as that on which the semiconductor chip 10 is mounted on the substrate 20 (such as a region outside of the semiconductor chip 10). That is, an electric connection terminal 40 involving the embodiment may be disposed on a surface opposite to a surface on which the semiconductor chip 10 is mounted or on a surface the same as that on which the semiconductor chip 10 is mounted (such as a region outside of the semiconductor chip 10).

In the embodiment, the electric connection portion 26 is provided with the electric connection terminal 40. The electric connection terminal 40 is an external terminal of the semiconductor device and may be formed in the shape of a ball. The ball-like shape does not necessarily mean a complete sphere but may be a part of a sphere or an agglomeration.

The electric connection terminal 40 includes a plurality of particles 42 made of a resin and a conductor film 44 that is coated on a surface of each of the particles 42. The electric connection terminal 40 includes a brazing material (such as solder) 46 that is a main component thereof, and in the brazing material 46 a plurality of particles 42 is dispersed. A composition of the brazing material 46, without restricting to a particular one, may be constituted of, for instance, tin (Sn) and a compound of other metal (such as silver (Ag) or copper (Cu)). The brazing material 46 may further include flux. The conductor film 44 may be a metal film (such as copper (Cu)) and can be formed by means of, for instance, a plating process (such as electroplating or electroless plating). The electric connection terminal 40 is a so-called resin dispersion solder ball.

According to the embodiment of the present invention, owing to the plurality of particles 42, the stress applied on the electric connection terminal 40 can be alleviated. In more detail, since the resin is softer than the brazing material 46, owing to the plurality of particles 42, the stress can be absorbed or dispersed. Furthermore, since the particles 42 are dispersed in plural, the unwetting with the brazing material 46 is difficult to occur. Still furthermore, since a surface of the particle 42 is coated with a conductor film 44, the electrical characteristics of the electric connection terminal 40 can be attained. For instance, even when a plurality of particles 42 is densely packed, the conductor films 44 come into contact each other. Accordingly, a current flows between the particles 42 and an insulating portion can be inhibited from expanding.

A component of the resin of the particles 42 is not particularly restricted and for instance polystyrene and divinylbenzene may be used. The particle 42 may be formed of a thermosetting resin. In this case, the particle 42 may be heat-cured one (such as one obtained by completely heat-curing or more than half heat-curing). According to this, when the electric connection terminal 40 is heated and melted (such as in a reflow process), the particle 42 does not melt (or difficult to melt). Accordingly, even after the heating and melting, a state where the plurality of particles 42 are dispersed can be maintained. As a result, after the heating and melting, the stress relief of the electric connection terminal 40 can be attained.

As shown in FIG. 3, a method of manufacturing an electric connection terminal according to the embodiment of the present invention will be explained. First, in a crucible 50, a plurality of resinous particles 42 is blended with a molten brazing material 46. Before blending, the particles 42 may have been heat-cured. Before blending, a surface of the particle 42 may be coated with a conductor film 44. As a coating method, the abovementioned plating process can be applied. A liquid electric connection terminal 40 (brazing material 46) obtained by heating and melting is dropped from a nozzle 52 and simultaneously cooled. At this time, to the dropping liquid electric connection terminal 40, a vibration having a predetermined direction, frequency and amplitude is transmitted. Thus, a liquid flow necks and becomes solid owing to the cooling, and thereby an electric connection terminal 40 is formed in ball.

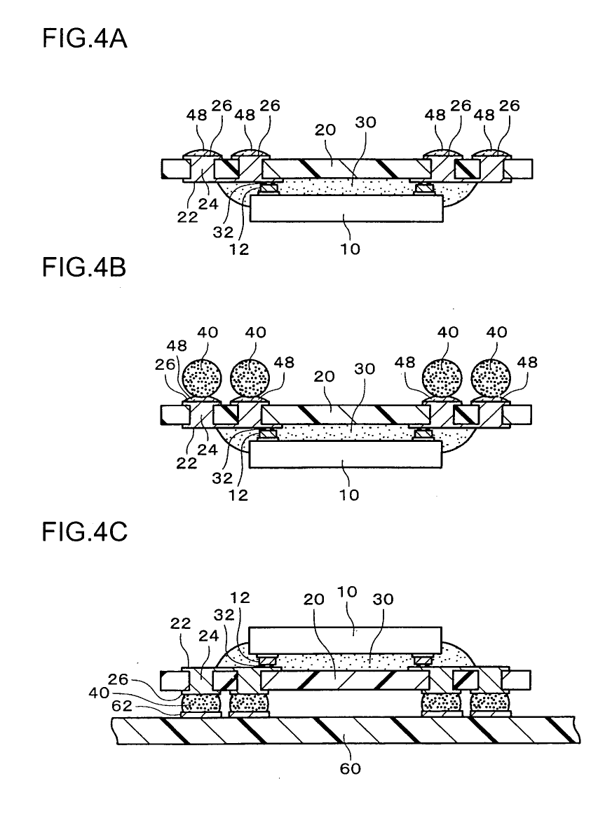

In the next place, as shown in FIGS. 4A through 4C, a method of mounting a semiconductor device according to the embodiment of the present invention will be explained. As shown in FIG. 4B, on an electric connection portion 26 (first electric connection portion) of a substrate 20 on which a semiconductor chip 10 is mounted, an electric connection terminal 40 is disposed. As shown in FIG. 4A, flux 48 may be previously disposed on the electric connection portion 26. The electric connection terminal 40 may be disposed on the flux 48. The flux surfaces on a surface of the brazing material 46 owing to the later heating and melting (not shown in FIG. 4C). The electric connection terminal 40 is formed in the shape of a ball. A method of disposing to the electric connection portion 26 is not restricted. For instance, when the throughhole 24 has a through hole different from an illustrated example, by sucking through the through hole, a ball-like electric connection terminal 40 may be sucked. As shown in FIG. 4C, a substrate 20 is aligned with a circuit board 60 and the electric connection terminal 40 is heated and melted (a reflow process). Subsequently, the electric connection portion 26 of the substrate 20 (first electric connection portion) and an electric connection portion 62 of the circuit board 60 (second electric connection portion) are electrically connected. According to the embodiment of the present invention, to the thermal stress during mounting and thereafter, the stress applied to the external terminal of the semiconductor device (electric connection terminal 40) can be alleviated.

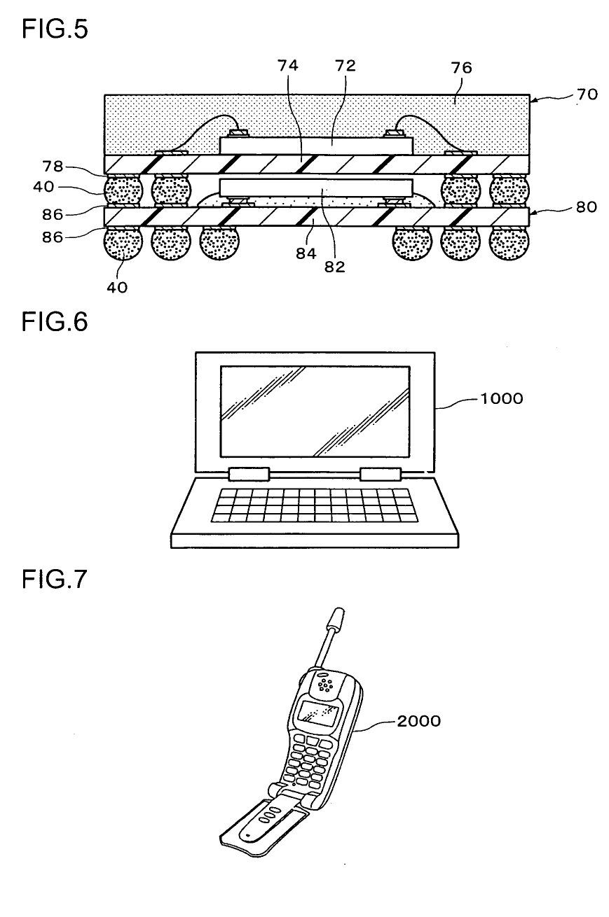

FIG. 5 is a diagram showing a modification of an example of a semiconductor device involving the embodiment. In an example shown in FIG. 5, a plurality of semiconductor devices is stacked. The semiconductor device (stacked semiconductor device) has first and second semiconductor devices 70 and 80 and the abovementioned electric connection terminal 40 is interposed therebetween so as to electrically connect the semiconductor devices above and below. In more detail, the first semiconductor device 70 has a semiconductor chip 72 and a substrate 74 on which the semiconductor chip 72 is mounted, and to the substrate 74 an electric connection portion (such as land) 78 is formed as a part of a wiring pattern. The semiconductor chip 72 is wire-bonded and an entirety thereof may be sealed with a resin sealing portion 76. The second semiconductor device 80 has a semiconductor chip 82 and a substrate 84 on which the semiconductor chip 82 is mounted, and to the substrate 84 an electric connection portion (such as land) 86 is formed as a part of a wiring pattern. The electric connection portion 86 may be formed on both surfaces of the substrate 84. The electric connection terminal 40 is interposed between the electric connection portion 78 of the first semiconductor device 70 and the electric connection portion 86 of the second semiconductor device 80. Thus, the stress applied on the external terminal between a plurality of semiconductor devices that is stacked can be alleviated. In an example shown in FIG. 5, to the second semiconductor device 80 at the lower-most layer, an electric connection terminal 40 is disposed on the electric connection portion 86 on a side of a surface opposite to the first semiconductor device 70. Thereby, the plurality of semiconductor devices that is stacked can be mounted on the circuit board. Effects thereof are as mentioned above. Different from an example shown in FIG. 5, the first and second semiconductor devices 70 and 80 may be sealed therebetween with a resin.

The present invention, without restricting to the abovementioned embodiments, may be variously modified. For instance, the invention includes a configuration substantially the same as that explained in the embodiment (such as a configuration the same in the function, method and result, or a configuration the same in the advantage and result). Furthermore, the invention includes a configuration in which a portion that is not essential to the configuration explained in the embodiment is replaced. Still furthermore, the invention includes a configuration that can exhibit an operational effect the same as that of the configuration explained in the embodiment or a configuration that can attain the same advantage. Furthermore, the invention includes a configuration in which a known technique is added to the configuration explained in the embodiment.

1. An electric connection terminal, comprising:
a brazing material;
a plurality of particles dispersed in the brazing material and made of a resin; and
a conductor film that coats a surface of each of the particles.

2. The electric connection terminal according to claim 1, wherein the particles are heat-cured and formed.

3. The electric connection terminal according to claim 1, wherein the electric connection terminal has a ball shape.

4. A method of manufacturing an electric connection terminal, comprising:
(a) blending a plurality of particles made of a resin in a molten brazing material; and
(b) cooling the brazing material and thereby forming the brazing material to have a ball shape for the electric connection terminal containing the plurality of particles.

5. The method of manufacturing an electric connection terminal according to claim 4, further comprising before blending, heat-curing the particles.

6. The method of manufacturing an electric connection terminal according to claim 4, further comprising before blending, coating a surface of each of the particles with a conductor film.

7. The method of manufacturing an electric connection terminal according to claim 4, wherein the conductor film is formed according to a plating process.

8. The method of manufacturing an electric connection terminal according to claim 4, wherein in cooling the brazing material, the brazing material is dropped to form a ball shape.

9. A semiconductor device, comprising:
a semiconductor chip;
a substrate on which the semiconductor chip is mounted;
an electric connection portion formed on the substrate; and
an electric connection terminal that is disposed at the electric connection portion and includes a brazing material, a plurality of particles dispersed in the brazing material and made of resin and a conductor film that is coated on a surface of each of the particles.

10. The semiconductor device according to claim 9, wherein the particles are heat-cured and formed.

11. The semiconductor device according to claim 9, wherein the electric connection terminal is formed in a ball shape.

12. An electronic device, comprising the semiconductor device according to claim 9.

13. A method of mounting a semiconductor device, comprising:
forming a ball-like electric connection terminal including a plurality of particles made of a resin;
disposing the electric connection terminal at a first electric connection portion of a substrate on which a semiconductor chip is mounted; and
aligning the substrate to a circuit board and melting the electric connection terminal to connect the first electric connection portion and a second electric connection portion of the circuit board.

14. The electric connection terminal according to claim 2, wherein the electric connection terminal has a ball shape.

15. The method of manufacturing an electric connection terminal according to claim 5, further comprising before blending, coating a surface of each of the particles with a conductor film.

16. The method of manufacturing an electric connection terminal according to claim 5, wherein a conductor film is formed according to a plating process.

17. The method of manufacturing an electric connection terminal according to claim 6, wherein a conductor film is formed according to a plating process.

18. The method of manufacturing an electric connection terminal according to claim 5, wherein in cooling the brazing material, the brazing material is dropped to form a ball shape.

19. The method of manufacturing an electric connection terminal according to claim 6, wherein in cooling the brazing material, the brazing material is dropped to form a ball shape.

20. The method of manufacturing an electric connection terminal according to claim 7, wherein in cooling the brazing material, the brazing material is dropped to form a ball shape.
